(19) United States
(12) Patent Application Publication
(10) Pub. No.: US 2006/0267185 A1
(43) Pub. Date: Nov. 30, 2006

(54) Encapsulated power semiconductor assembly

(75) Inventor: Andreas Lindemann, Lampertheim (DE)

Correspondence Address: HESLIN ROTHENBERG FARLEY & MESITI PC, 5 COLUMBIA CIRCLE, ALBANY, NY, 12203, US

(73) Assignee: IXYS SEMICONDUCTOR GMBH, Lampertheim (DE)

(21) Appl. No.: 10/552,032

(22) PCT Filed: Apr. 8, 2004
(86) PCT No.: PCT/EP04/03750

§ 371 Date: Oct. 3, 2005

(30) Foreign Application Priority Data
Apr. 9, 2003 (DE) 103 16 136.8

(51) Int. Cl. H01L 23/34

(52) U.S. Cl. 257/723

(57) ABSTRACT

The invention relates to an encapsulated power semiconductor assembly comprising a substrate consisting of an insulation material (ceramic), provided with a plurality of islands, which are composed of a thermal conductive material, in particular of partial surfaces of a metal layer. Power semiconductor chips are soldered onto said islands. Electric connections that run from the chips to the connecting elements are produced in the form of bonding pads on additional islands or in the form of wires and islands that are configured as printed conductors. The substrate and the chips are encapsulated, whereas the connection elements project beyond said encapsulation and the metallic underside of the substrate is exposed in order to be fastened to a heat sink.

### SCOPE OF THE INVENTION

The invention relates to an encapsulated power semiconductor assembly in which a plurality of power semiconductor chips is encapsulated.

### STATE OF THE ART

Power semiconductors are being used increasingly in systems where the voltage is supplied by batteries, particularly in motor manufacture. At voltages of 12 to 80 V high currents imposing considerable demands on the power switches are often generated. In the state of the art encapsulated semiconductor chips are used for switching high currents. A method is known for encapsulating several chips simultaneously using a conductor frame, as described for example in DE 26 36 450 C2 and U.S. Pat. No. 4,507,675. The individual power semiconductor components, each provided with one chip, are then separated again.

The feed cables to the chips, which depart from connecting elements projecting from the enclosure, are often dimensioned, because of the construction of the power semiconductor assembly, so that the feed cables exhibit undesirably high resistances, resulting in heating effects. Moreover parasitic inductances, resulting in overvoltage effects, also frequently occur.

An encapsulated power semiconductor assembly, with only one chip, is described in WO 00/07238. Here the chip is applied to a ceramic substrate which is coated at the top and bottom with copper. Such ceramic substrates are also referred to as direct-copper-bond substrates. They have the advantage that on the one hand the chip is electrically insulated from the cooling element and on the other that the heat is dissipated into the cooling element.

A method is known from EP 0063070 A1 for combining a plurality of power semiconductor chips. Here two chips, not electrically connected, are applied to a plate with good thermal conduction and are connected to connection elements. The heat is dissipated through the plate to a baseplate.

A method is also known for arranging a larger number of components on a metal comb which is embedded with plastic except for one cooling surface (BBC BROWN BOVERI, Power semiconductors, Dr. Heimo Buri, Mannheim 1982). The individual components are then separated again. This embedding technique is used when smaller components are to be manufactured at low cost in large quantities.

An assembly for diodes, which is provided with a flat aluminium oxide carrier, which is metallised over part of the surface, is known from DE 697 10 885 T2. The diodes are mounted on the metallisation. Contact faces, which are connected electrically to the diodes by connecting elements which penetrate the carrier, are provided on the side of the carrier opposite the diodes.

De 196 35 582 C1 describes a power semiconductor component provided with a surface mountable housing, which encloses a chip which is applied to a metal plate.

### SUMMARY OF THE INVENTION

The object of the invention is to provide a power semiconductor assembly, which can be manufactured at low cost, with a plurality of chips which has improved properties, and in particular dissipates heat more efficiently to the cooling element, in which fewer overvoltages and fewer parasitic inductive effects are generated, and in which the chips can at least in part be electrically connected to each other.

This object is achieved with the characteristics of claim 1.

Advantageous embodiments of the invention constitute the object of the sub-claims.

Since the chips are placed on thermally conducting islands, preferably on several islands, and in particular each individual chip is placed on a separate island, the heat from the chips is not transferred to a closed conductor layer but only to an insulated, i.e. separate area. From this area the heat is then transferred directly into the insulator substrate and can be discharged downwards from this substrate. For example, the heat can be transferred to a metal layer which is arranged on the bottom of the substrate and is not enclosed, i.e. remains exposed, so that the heat can be discharged onto a cooling element. The electrical connections are then heated to a lesser degree or hardly at all.

The thermally and electrically conductive material is preferably a metal, in particular in the form of a thin layer.

The arrangement of the islands, with and without chips, enables the electrical connections to be optimised. The electrical connections may include soldered connections, (bond) wire connection or even connections via the islands. In optimising the layout of the connecting elements consideration may be given to parasitic inductances, e.g. by arranging connecting elements conducting a main current adjacent to each other. To ensure that excessively high voltages are not applied to adjacent connecting elements, the islands are preferably designed so that at least there is a general tendency for such connecting elements which are provided with potentials which display a low potential difference (voltage) to be arranged closer to each other than the connecting elements provided with potentials which display a high potential difference. The connecting elements may be arranged on two sides, in particular opposite sides, of the enclosure and project from it. They are flat conductor connections which may be bent inside or outside the enclosure. The conductor connections need not all have the same dimensions, nor need they be arranged at the same distance from each other. For example, they may be narrower on one side of the enclosure and exhibit shorter distances to their nearest neighbour than on the other side of the enclosure. The wider conductor connections on one side of the enclosure may also be less numerous than the narrow connections are on the other side of the enclosure. A slot or recess may be provided in the enclosure underneath the conductor connections for receiving an insulator, for example a plastic film, so that if there is contact between the metallised bottom of the substrate and a heat sink, the conductor connections are separated from the heat sink, to avoid electrical short-circuits.

In the invention use is made of a metallised ceramic substrate, for example a direct-copper-bond substrate or a direct-aluminium-bond substrate in which the ceramic material may contain aluminium oxide and/or aluminium nitride. The chips may be soldered onto the metal islands.

A plurality of different chips may be used, e.g. MOSFET, diode, IGBT and/or thyristor chips, which may, in their interaction for example, form an individual switch, a chopper, a phase displacer, an H-bridge or a threephase bridge, or a combination of these elements.

### BRIEF DESCRIPTION OF THE DRAWING

A preferred embodiment of the invention is described below with reference to a drawing in which:

FIG. 1 shows a diagrammatic internal view of a section of the power semiconductor assembly according to the invention in a plan view,

FIG. 2 shows a power semiconductor assembly according to the invention in a plan view,

FIG. 3 shows the power assembly in a bottom view,

FIG. 4 shows a section of the power semiconductor assembly in a sectional and enlarged representation, and

FIG. 5 shows a wiring diagram of a combination of six power semiconductor chips for an embodiment of the invention.

### DESCRIPTION OF A PREFERRED EMBODIMENT OF THE INVENTION

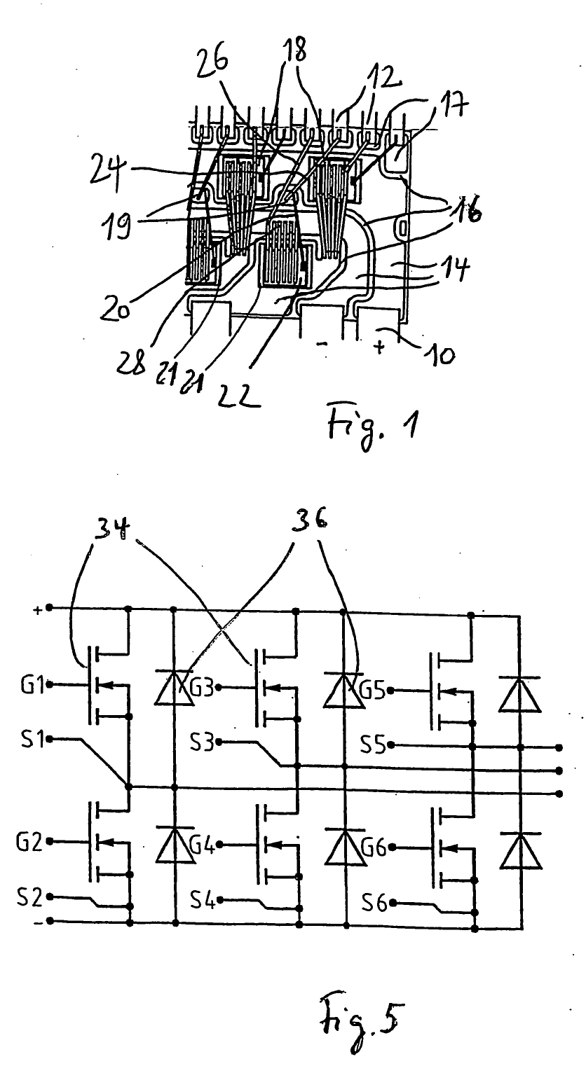

FIG. 1 shows a view of a power semiconductor assembly in which three connecting elements 10 may be seen at the bottom of the figure, and eight connecting elements 12 may be seen opposite at the top of the figure, which elements 12 are considerably narrower and are closer to each other than connecting elements 10. Islands, consisting of a thermally and electrically conductive insulation material, are located on the top of the substrate, which consists of a ceramic insulation material. These islands are formed by a metal layer and are separated by pits 16 which have been produced by etching. The metal layer islands serve as the electrical connection and for securing connecting elements 10 and power semiconductor chips 22.

Upper connecting elements 12 are each connected mechanically and electrically to adjacent islands 17 on the upper edge of the substrate, and upper connecting elements 10 are connected electrically and mechanically to islands 14 designed as a strip line. Power semiconductor chips 22 are soldered onto islands 21 in the central area of the substrate. Furthermore, slightly smaller metal layer islands 19 are provided between two strip lines 14, which islands serve to bond wires on for electrical connection of the semiconductor chips to the connecting elements. What is shown, for example, is a bond wire 20 which leads from a chip 22 to an island 19. A further bond wire 24 then makes the connection to a connecting element 12 which is in turn connected to an island. A third bond wire 26 is fed from chip 22 via a strip line 14 to a connecting element 12. Moreover, the chip is connected by a plurality of adjacent wires 28 to a conductor region 14. The electrical connections of the other chips are similarly made. The +, − current connections are arranged immediately adjacent to each other to reduce inductances, and the current conducting strip lines do not form a conductor loop.

The metal layer is a copper layer which is applied to a relatively thin ceramic substrate which is approximately 0.38 mm thin, preferably less than 1.0 mm. This suffices as insulation for voltages used in motor manufacture, i.e. voltages which are not too high. On the back the ceramic substrate is also coated with copper. A direct-copper-bond substrate is therefore used.

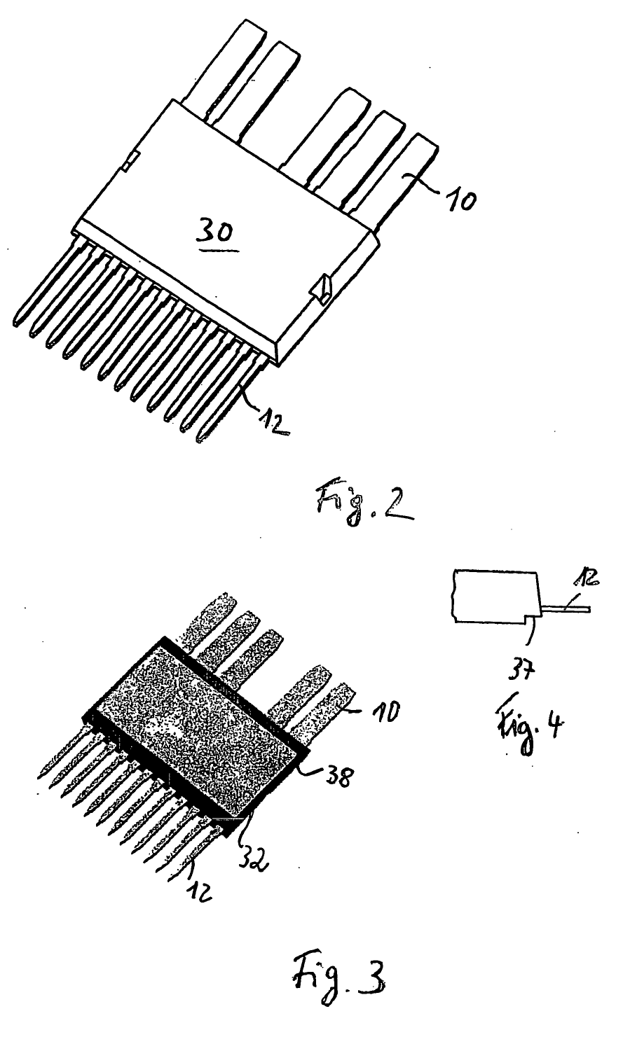

FIG. 2 shows the power semiconductor assembly according to the invention in plan view. The power semiconductor chips are enclosed by a monolithic enclosure 30 of plastic which is pressed around the ceramic substrate. This embedding technique is known to the expert. The enclosure extends over the entire top of the substrate and engages in the bottom of the substrate. Connecting elements 10, 12 project from enclosure 30 in the form of flat conductor connections. In the view of the same power semiconductor assembly from below, shown in FIG. 3, it is seen that the substrate is not fully enclosed by the enclosure but that the lower metal layer 32 is exposed and is surrounded by a narrow peripheral edge 38 of the enclosure. The power semiconductor assembly may therefore be easily connected to a heat sink. The enclosure recedes on the narrow peripheral edge, forming shoulders 37, so that narrow gaps are formed when the semiconductor assembly rests on a cooling element with the lower metal layer (FIG. 4). A flat insulator, which is pushed underneath the conductor connections, may extend into this gap. The insulator, for example a small plastic plate, serves to prevent short-circuits between the conductor connections and the cooling element and also to increase the voltage resistance.

The different chips may be ideally interconnected with the power semiconductor assembly according to the invention. As an example, FIG. 5 shows the connection of six elements as a threephase bridge. Each element contains a MOSFET 34 with gate connection G1, G2, G3, G4, G5 and G6, and source connection S1, S2, S3, S4, S5 and S6, as well as a diode 36, which may either be part of a MOSFET or may also be separate in the form of a Shottky diode. Otherwise connections not shown here may form an H-bridge or phase displacer.

1. Encapsulated power semiconductor assembly with:
a substrate of a ceramic insulation material with islands comprising a thermally and electrically conductive material,
at least two power semiconductor chips arranged on the islands,
electrical connections from the chips to connecting elements, wherein at least two connecting elements are electrically connected to the islands,
wherein
an enclosure of pressed plastic material is provided which fully surrounds the power semiconductor chips and at least partially surrounds the substrate, wherein the connecting elements are designed as flat conductor connections projecting from the enclosure, and the substrate exhibits a metal coating on a side opposite the islands.

2. Power semiconductor assembly according to claim 1, wherein the islands include separate partial surfaces of a metal layer.

3. Power semiconductor assembly according to claim 1, wherein the substrate is a ceramic substrate which contains, aluminium oxide or aluminium nitride ceramic material.

4. Power semiconductor assembly according to claim 1, wherein the metal coating of the substrate is at least partially exposed on the side opposite the islands.

5. Power semiconductor assembly according to claim 1, wherein the substrate is a direct-copper-bond or direct-aluminium-bond substrate.

6. Power semiconductor assembly according to claim 1, wherein the electrical connections comprise soldered connections.

7. Power semiconductor assembly according to claim 1, wherein the electrical connections comprise wire connections and/or connections via the islands.

8. Power semiconductor assembly according to claim 1, wherein the connecting elements are located on two different sides of the enclosure.

9. Power semiconductor assembly according to claim 1, wherein the connecting elements are arranged and connected to the chips so that connecting elements conducting a main current are arranged adjacent to each other.

10. Power semiconductor assembly according to claim 1, wherein the connecting elements are arranged and connected to the chips so that two connecting elements, which are provided with potentials which have a high mutual potential difference, are arranged further from each other than two connecting elements with potentials which have a low mutual potential difference.

11. Power semiconductor assembly according to claim 1, wherein the chips are secured to a metal island by means of soldered connections.

12. Power semiconductor assembly according to claim 1, wherein at least one shoulder is formed on a bottom of the enclosure for inserting a flat insulator.

13. Power semiconductor assembly according to claim 1, wherein the chips comprise MOSFET, diode, IGBT and/or thyristor chips.

14. Power semiconductor assembly according to claim 1, wherein the chips, when interacting, form an individual switch, a chopper, a bridge branch, an H-bridge or a threephase bridge or a combination of these elements.
